(19) United States
(12) Patent Application Publication
(10) Pub. No.: US 2021/0217968 A1
(43) Pub. Date: Jul. 15, 2021

(54) POROUS PEROVSKITE FILMS

(71) Applicant: The University of Manchester, Mnchester (GB)

(72) Inventors: Brian Saunders, Mnchester (GB); Chotiros Dokkhan, Mnchester (GB); Muhamad Z. Mokhtar, Mnchester (GB); Yun Xiao, Mnchester (GB)

(21) Appl. No.: 17/057,360

(22) PCT Filed: May 23, 2019
(86) PCT No.: PCT/GB2019/051429

§ 371 Date: Nov. 20, 2020

(30) Foreign Application Priority Data
May 23, 2018 (GB) 1808461.6

(51) Int. Cl. H01L 51/00; C09K 11/06; C09K 11/02; H01G 9/00; H01G 9/20; H01L 51/42

(52) U.S. Cl. CPC H01L 51/0077; C09K 11/06; C09K 11/02; H01L 51/004; H01L 51/0043; C09K 2211/10; H01G 9/2009; H01L 51/0007; H01L 51/0028; H01L 51/4253; H01G 9/0036

(57) ABSTRACT

This invention relates to porous perovskite photoactive films, and more particularly, to porous perovskite films containing microgels. The present invention also relates to processes for the preparation of these films and to their use in perovskite solar cells.

This invention relates to porous perovskite photoactive films, and more particularly, to porous perovskite films containing microgels. The present invention also relates to processes for the preparation of these films and to their use in perovskite solar cells.

### BACKGROUND

Perovskite solar cells (PSCs) continue to generate enormous research interest in the field of renewable energy generation, because of their meteoric rise in power conversion efficiencies (PCEs), thereby offering the potential for low-carbon energy generation. PSCs contain a light harvesting photoactive layer, the layer being formed from a compound with an ABX₃ perovskite crystal structure.

Hybrid organic-inorganic halide perovskites are an important class of perovskite compounds. This is due to the near optimum balance of perovskite material properties that suit their use as light harvesting layers in solar cells. These properties include panchromatic absorption (Kazim et al., Angewandt. Chem. Int. Ed., 2014, 53, 2812-2824), low exciton binding energies (Miyata et al., Nat. Phys., 2015, 11, 582), high exciton diffusion lengths (Stranks et al., Science, 2013, 342, 341-344) and defect tolerant performance (De Marco et al., Nano Lett., 2016, 16, 1009-1016). Pb-based perovskites provide the highest power conversion efficiencies and are based on earth-abundant materials (Frost et al., Acc. Chem. Res. 2016, 49, 528-535).

An area of future energy generation is building-integrated solar cells, which involve semi-transparent solar cells for windows or interior walls. Hence, there is considerable interest in establishing semi-transparent PSCs. One method to achieve such PSCs involves including controlled porosity within deposited perovskite photoactive films (Eperon et al., ACS Nano, 2014, 8, 591-598).

Inverse opal (IO) films consist of highly ordered monodisperse pores and have been widely studied for optical and electronic applications (Wang et al., ACS Nano, 2017, 11, 8026-8033). IO perovskite films are prepared using multi-step approaches involving colloidal particle templates which are subsequently removed (Meng et al., Nano Lett., 2016, 16, 4166-4173; Zhou et al., Adv. Mater., 2017, 29, 170368). The IO perovskite films reported to date have tuneable reflectivity and respectable PCEs, but unfortunately, existing methods to prepare IO films use delicate procedures that are time-consuming. Their future scale-up in a cost-effective manner for PSCs is a daunting challenge. In contrast, disordered inverse opal (DIO) morphologies are arguably more relevant to future large-scale applications (Neale et al., J. Phys. Chem. C, 2011, 115, 14341-14346). Such morphologies can provide strong light scattering and are of interest for enhancing solar cell performance. It is therefore desirable to establish a scalable method to give porous perovskite films with a DIO morphology.

Microgels (MGs) are crosslinked polymer colloid particles that swell in a thermodynamically good solvent (Saunders et al., Adv. Coll. Interf Sci., 1999, 80, 25). They have been used for many years to form surface coatings in the automotive industry and have unique rheological and reversible space-filling properties. In order to stabilize PSCs and reduce the amount of expensive hole transport material used, polystyrene microgels have been used as an encapsulating layer on top of perovskite films (Chen et al., Nanoscale, 2017, 9, 10126-10137); such use, however, was found to reduce the PCEs compared to control PSCs.

It is therefore an object of the present invention to obviate or mitigate one or more of the problems of the prior art, whether identified herein or elsewhere.

### SUMMARY OF THE DISCLOSURE

The present invention provides novel porous perovskite films comprising microgel particles within the photoactive perovskite layer. A micropatterning approach uses microgels as pore-forming particles to produce perovskite films, typically with a DIO morphology. The present invention also provides a scalable method for depositing such porous perovskite films in a single step. The microgels increase the perovskite capping layer thickness as well as the grain size and perovskite conversion. Advantageously, the microgels increase the extent of light harvesting and photoluminescence (PL) intensity of the perovskite phase. Furthermore, the presence of the microgels also increases the PCE of perovskite solar cells fabricated with porous perovskite films according to the present invention, compared to microgel-free control PSCs.

Therefore, in a first aspect, the present invention provides a porous photoactive layer for a perovskite solar cell, the layer comprising:

a hybrid inorganic-organic perovskite of formula ABX₃, wherein:
A is C₁₋₆alkyl-NH₃⁺ and optionally also includes one or more of Cs⁺, Rb⁺, B²⁺, and formamidinium;
B is selected from Pb²⁺ and Sn²⁺; and
X is selected from one or more of Br, Cl⁻ and I⁻;
provided that A and B balance the X⁻ charge, so that overall A is singly-charged and B is doubly-charged; and
   a plurality of microgel particles formed from a hydrophilic crosslinked polymeric material capable of swelling in polar aprotic solvents.

In another aspect, the present invention provides a method of forming a porous photoactive layer as described herein, comprising the steps of:
a) swelling particles of the microgel in a solvent to 1.2-100 times the size of the unswollen particles;
b) adding hybrid inorganic-organic perovskite precursors to the dispersion of swollen microgel particles from step a);
c) coating the dispersion from step b) onto a substrate; and
d) evaporating the solvent.

In a further aspect, the present invention provides a perovskite solar cell comprising a porous photoactive layer as described herein.

The above and further aspects of the invention are described in further detail herein.

### BRIEF DESCRIPTION OF THE DRAWINGS

[The code used to denote the films referred to below is ‘MPxMGy’ where x and y are the concentrations of MAPbl_{3-z}Cl_{z} and MG used to prepare the films. Note that MA is CH₃NH₃⁺].

Particular embodiments of the invention are further described hereinafter with reference to the accompanying drawings, in which:

FIG. 1 shows (A) scanning electron microscopy (SEM) images of PNVF-NVEE microgels (MGs), prepared according Method 2 (M2), deposited from DMSO, illustrating their tendency to form hexagonally close packed clusters; (B) size distribution measured using dynamic light scattering (DLS) for the M2 MGs dispersed in ethanol and DMSO; (C) atomic force microscopy (AFM) image and a line profile of individual M2 MGs after being deposited from DMSO. The AFM data were measured in air (scale bars are 1000 nm); (D) size distribution measured using dynamic light scattering (DLS) for the MGs prepared according Method 3 (M3) dispersed in ethanol and DMSO; (E) and (F) SEM images of the M3 MGs deposited from ethanol and DMSO respectively (scale bars are 5 μm).

FIG. 2 shows optical micrographs of M2 MGx films deposited on microscope slides according to Method 4. The value for x is the MG concentration used (i.e., C_{MG}). The C_{MG} values used to prepare the films were (A) 1.0, (B) 2.0, (C) 3.0, (D) 4.0, (E) 5.0, (F) 6.0 and (G) 7.0 wt. %. (H) shows the fractional surface coverage measured from (A) to (G) plotted as a function of C_{MG}.

FIG. 3 shows a schematic of a proposed mechanism for porous perovskite layer formation using MGs as micropatterning additives during spin coating as the exemplary coating method. The precursor solution containing MGs (A) is spin coated which causes the MGs to be deposited onto the substrate surface (B). Crystallization of the hybrid inorganic-organic perovskite (HIOP) may be accelerated by anti-solvent addition, which causes the MG shell to initially collapse (C). Crystallization of the perovskite occurs more rapidly than MG de-swelling. Crystal growth occurs for the longest periods of time beside the MGs (D). Finally, solvent is completely removed from the MG core and the particles are flattened to leave pores which form the DIO film (E).

FIG. 4 shows optical micrographs obtained for M2 MPxMGy films prepared using various compositions according to Method 5. Scale bars=20 μm.

FIG. 5 shows optical micrographs obtained for M2 (A) MP25MG3.0, (B) MP37.5MG3.0, (C) MP45MG2.0, (D) MP25, (E) MP37.5 and (F) MP45 films prepared according to Method 5. The scale bars are shown.

FIG. 6 shows a phase diagram constructed using SEM images measured for M2 MPxMGy films prepared using various compositions according to Method 5. The shaded area shows the region of the phase diagram where DIO films were found. MG-rich and MAPbl_{3-z}Cl_{z} (MP)-rich regions are identified. Scale bars=5 μm.

FIG. 7 shows lower magnification SEM images obtained for M2 (A) MP25MG3.0, (B) MP37.5MG3.0, (C) MP45MG2.0, (D) MP25, (E) MP37.5 and (F) MP45 films prepared according to Method 5. Scale bars=5 μm.

FIG. 8 shows SEM images obtained for M2 (A) MP25MG3.0, (B) MP37.5MG3.0, (C) MP45MG2.0, (D) MP25, (E) MP37.5 and (F) MP45 films. Hexagonal packing is illustrated in A-C. SEM images are also shown for (G) MP30MG2.0, (H) MP30MG3.0 and (I) MP30MG4.0. The arrows in (G) show that DIO islands formed around the MGs. Scale bars=5 μm.

FIG. 9 shows SEM images obtained for M3 (A) MP30MG4.0, (B) MP30MG3.0, (C) MP30MG1.0 and (D) MP30 films. The scale bar values shown for (A) apply to all images.

FIG. 10 shows (A) High magnification SEM image obtained of the M2 MP37.5MG3.0 DIO film showing two pores with MGs visible; (B) SEM image for a cross-section for the film from (A) with two pores evident. One pore is indicated by the black dashed lines and had an approximate diameter of 800 nm. The large white arrows in (A) and (B) highlight flattened MGs. Scale bars=300 nm.

FIG. 11 shows SEM images for (A) M3 MGs deposited from DMSO; and (B) to (F) SEM images obtained for M3 MP30MGy films prepared using various compositions according to Method 5—(B) and (C) for (30, 4.0) films; (D) and (E) for (30, 3.0) films; (F) cross-section SEM image for a (30, 4.0) film. The black arrows highlight MGs.

FIG. 12 shows tapping mode AFM images and line profiles measured for M2 (A) MP25MG3.0, (B) MP37.5MG3.0 and (C) MP45MG2.0 films. Scale bars=1.0 μm.

FIG. 13 shows (A) XRD patterns of various M2 films as indicated; (B) variation of the average grain size determined from the application of the Scherrer equation to the perovskite peaks from (A).

FIG. 14 shows UV-visible spectra for M2 (A) MPxMG3.0 and (B) MP30MGy films. The insets for (A) and (B) show the effects of MP and MG concentration, respectively, on the absorbance values.

FIG. 15 shows photoluminescence (FL) spectra for M2 (A) MPxMG3.0 and (B) MP30MGy films. The insets for (A) and (B) show the effects of MP and MG concentration, respectively, on the PL intensity. The value for λₑₓ was 480 nm.

FIG. 16 shows (A) Transmittance spectra for M3 MP30MGy films; (B) The effect of MG concentration (y) on the average visible transmittance (AVT) of M3 MP30MGy films; (C) PL spectra for M3 MP30MGy films; (D) The effect of y on the wavelength at maximum PL intensity (λₘₐₓ) for the M3 MP30MGy films.

FIG. 17 shows (A) schematic of solar cell device architecture prepared according the Method 6; (B) representative (current, J, voltage, V) J-V curves measured for various devices (labelled), made according to Method 6 using M2 MPxMGy films prepared using various compositions.

FIG. 18 shows figures of merit for six types of PSCs prepared according to Method 6. The DIO-based devices were M25MG3.0, MP37.5MG3.0 and MP45MG2.0. The other devices were controls. (A) Average short-circuit current density (J_{sc}) and fill factor (FF) (B) Average open circuit voltage (V_{oc}) and power conversion efficiency (PCE). (Student's t-test, *p<0.05 and **p<0.01).

### DETAILED DESCRIPTION

### Porous Perovskite Layers

The present invention provides a porous photoactive layer for a perovskite solar cell, the layer comprising:

a hybrid inorganic-organic perovskite of formula ABX₃, wherein:
A is C₁₋₆alkyl-NH₃⁺ and optionally also includes one or more of Cs⁺, Rb⁺, Ba²^{⁺}^{, and formamidinium;}
B is selected from Pb²⁺ and Sn²⁺; and
X is selected from one or more of Br, Cl⁻ and I⁻;
provided that A and B balance the X⁻ charge, so that overall A is singly-charged and B is doubly-charged; and
   a plurality of microgel particles formed from a hydrophilic crosslinked polymeric material capable of swelling in polar aprotic solvents.

Photoactive layers are used in solar cells to absorb light. In perovskite solar cells (PSCs), a photoactive layer includes a perovskite-structured material with a crystal structure of general formula ABX₃. Hybrid inorganic-organic perovskite compounds are a major class of compounds used as photoactive layers in PSCs.

The photoactive layer of the present invention comprises a hybrid inorganic-organic perovskite of formula ABX₃, as described herein. A and B must balance the X⁻ charge, so that overall A is singly-charged and B is doubly-charged. In other words, there are three X⁻ anions, so to balance the charge, overall, even though A and B may be combinations of different cations, A must be A⁺ and B must be B²⁺. For example, A is C₁₋₆alkyl-NH₃⁺ and B is (Sn²⁺)_{0.3}(Pb²⁺)_{0.7}; or A is (Cs⁺)_{0.5}(C₁₋₆alkyl-NH₃⁺)_{0.5} and B is Pb²⁺.

In an embodiment, A is C₁₋₆alkyl-NH₃⁺. C₁₋₆alkyl refers to a branched or unbranched alkyl chain containing between 1 and 6 carbon atoms. In an embodiment, C₁₋₆alkyl is methyl. In an embodiment, A is CH₃NH₃⁺. Formamidinium refers to the protonated form of formamidine.

In an embodiment, B is Pb²⁺.

In an embodiment, X is selected from one or more of Br and I⁻. In an embodiment, X is selected from one or more of Br and Cl⁻. In an embodiment, X is selected from one or more of Cl⁻ and I⁻. In an embodiment, X is a combination of Cl⁻ and I⁻.

In an embodiment, A is C₁₋₆alkyl-NH₃⁺ and B is Pb²⁺. In an embodiment, A is CH₃NH₃⁺ and B is Pb²⁺. In an embodiment, A is C₁₋₆alkyl-NH₃⁺, B is Pb²⁺ and X is selected from one or more of Cl⁻ and I⁻, preferably a combination of Cl⁻ and I⁻. In an embodiment, A is CH₃NH₃⁺, B is Pb²⁺ and X is selected from one or more of Cl⁻ and I⁻, preferably a combination of Cl⁻ and I⁻. In an embodiment, the porous photoactive layer comprises a hybrid inorganic-organic perovskite of formula (CH₃NH₃⁺)(Pb²⁺)(I⁻)_{3-z}(Cl⁻)_{z} where z is 0 to 3.

The hybrid inorganic-organic perovskites are typically prepared by mixing perovskite precursors in a suitable solvent. A suitable solvent, or solvent system, is one in which the precursors dissolve. Suitable solvents include polar aprotic solvents, such as dimethyl formamide (DMF) or dimethyl sulfoxide (DMSO). Suitable solvents may be selected from γ-butyrolactone, dimethyl formamide, dimethyl sulfoxide, or a combination of these solvents. In an embodiment, the hybrid inorganic-organic perovskite is formed from perovskite precursors. The hybrid inorganic-organic perovskite precursors are compounds which, when combined, are capable of forming a hybrid inorganic-organic perovskite of formula ABX₃, as defined herein. In a preferred embodiment, the precursors are of the formula AX and BX₂. In a preferred embodiment, the precursors are C₁₋₆alkyl-NH₃X and PbX₂, such as CH₃NH₃X and PbX₂ (for example, CH₃NH₃I and PbCl₂). In an embodiment, the hybrid inorganic-organic perovskite is of formula (CH₃NH₃⁺)(Pb²⁺)(I⁻)_{3-z}(Cl⁻)_{z} where z is 0 to 3; and is formed from the precursors CH₃NH₃I and PbCl₂.

In the present invention, microgels are used as a micropatterning additive for hybrid inorganic-organic perovskite photoactive layers. The microgels act as pore-forming agents around which the hybrid inorganic-organic perovskite crystallises during layer deposition. In contrast to some previously reported methods to prepare porous perovskite layers (Meng et al., Nano Lett., 2016, 16, 4166-4173; Zhou et al., Adv. Mater, 2017, 29, 170368) where the patterning additive was removed, the porous layers of the present invention are prepared via a single-step deposition method without the need to subsequently remove the microgel particles.

In order to prepare the porous photoactive layers according to the present invention, microgels were used which dispersed in solvents suitable for hybrid inorganic-organic perovskite preparation (polar aprotic solvents such as γ-butyrolactone, dimethyl formamide, and dimethyl sulfoxide), without dissolving. It is important that the microgels are also capable of swelling in polar aprotic solvents. ‘Good’ solvents for swelling microgels as described herein are therefore polar aprotic solvents such as γ-butyrolactone, dimethyl formamide, and dimethyl sulfoxide. ‘Poor’ solvents for swelling microgels as described herein are polar protic solvents such as ethanol or methanol, or non-polar solvents such as toluene, hexane or diethyl ether.

Accordingly, the porous photoactive layer of the present invention further comprises a microgel comprising a plurality of microgel particles formed from a hydrophilic crosslinked polymeric material capable of swelling in polar aprotic solvents.

The crosslinked polymeric material should be hydrophilic to enable it to be dispersed and swelled in polar aprotic solvents (such as γ-butyrolactone, dimethyl formamide, and dimethyl sulfoxide). Hydrophilic polymers may result from the co-polymerisation of monomers bearing hydrophilic moieties (such as hydrogen bond donor/acceptor moieties). In an embodiment, the microgel particles are prepared by non-aqueous dispersion polymerisation. Preferably, the microgel particles are prepared by non-aqueous dispersion polymerisation of monomers bearing hydrophilic moieties. Preferably the monomers are vinyl monomers bearing hydrophilic moieties. Preferably, the polymerisation is a free-radical co-polymerisation initiated via a suitable free-radical source such as AIBN. In an embodiment, the polymerisation is carried out in the presence of additional vinyl co-polymer stabilisers, such as polyvinylpyrrolidone/polyvinyl acetate co-polymer (PVP-co-PVA).

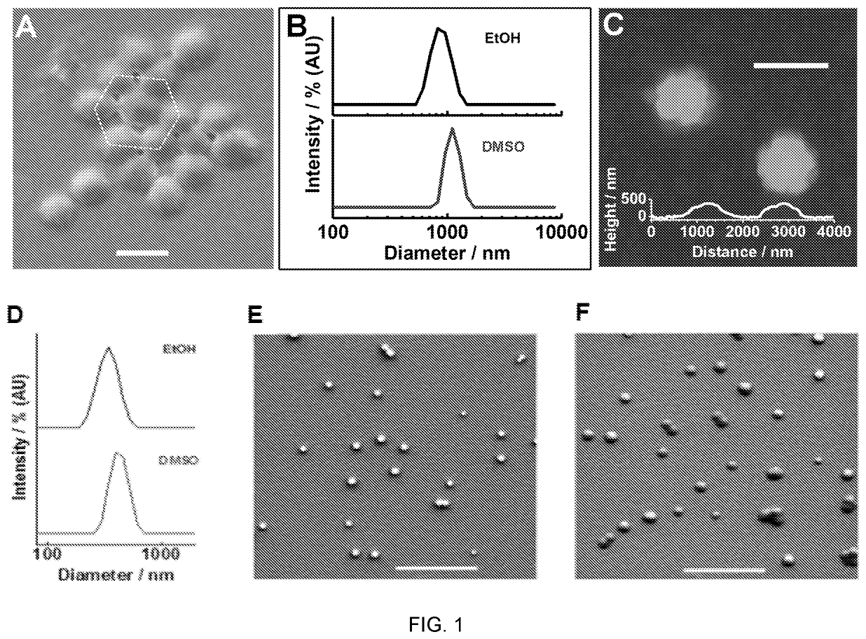

The swelling capability of the polymerized microgel particles can be assessed by comparing the z-average diameters (d_{z}) of the microgel particles (MGs) dispersed in a poor solvent (e.g. ethanol) and a good solvent (e.g. DMSO) via a suitable technique such as dynamic light scattering. This comparison can be seen in FIG. 1B, where the d_{z} values for this particular microgel in ethanol and DMSO, were measured at 885 nm and 1125 nm respectively, and also in FIG. 1D, where the d_{z} values for this smaller microgel in ethanol and DMSO, were measured at 354 nm and 495 nm respectively According to this invention, a microgel is capable of swelling in polar aprotic solvents, if the particles have z-average diameters in polar aprotic solvents 1.2 to 100 times greater than the z-average diameters in poor solvents such as ethanol, which do not swell the MGs (this is termed the ‘linear swelling ratio’). In an embodiment, the porous photoactive layer of the present invention comprises a microgel comprising a plurality of microgel particles formed from a hydrophilic crosslinked polymeric material capable of swelling in polar aprotic solvents, with a linear swelling ratio of between 1.2 100 compared to the unswollen particles. For the FIG. 1B example, the linear swelling ratio was 1.27, whereas for the FIG. 1D example, the linear swelling ratio was 1.40. In a preferred embodiment, the linear swelling ratio is between 1.2 and 50, such as between 1.2 and 25, between 1.2 and 10, or between 1.2 and 5 compared to the unswollen particles. The MG particle volume swelling ratios can also be estimated from the dynamic light scattering data. For the FIG. 1B example, the volume swelling ratio was 2.1, whereas for the FIG. 1D example, the volume swelling ratio was 2.7. In a preferred embodiment, the volume swelling ratio is between 1.5 and 10, such as between 1.5 and 5, between 1.5 and 3, or between 2 and 3 compared to the unswollen particles. Swollen MGs have good dispersion stability (i.e. they remain separated in dispersion), because the particles have a negligible effective Hamaker constant (Saunders et al., Adv. Coll. Inter. Sci., 1999, 80, 25).

In an embodiment, the microgel particles comprise a co-polymer of monomers (I) and (II):

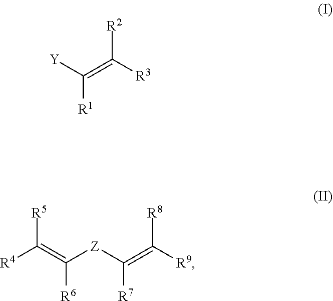

wherein:
Y is selected from:

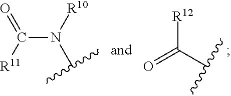

Z is selected from one of the following linkers:

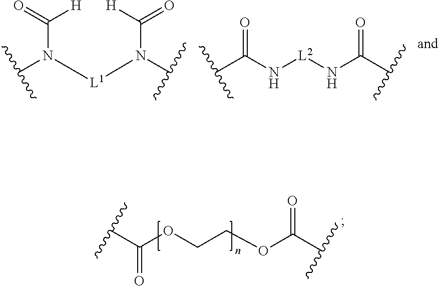

R¹, R², R³, R⁴, R⁵, R⁶, R⁷, R⁸ and R⁹ are independently selected from hydrogen and C₁₋₃alkyl;
R¹⁰ and R¹¹ are independently selected from hydrogen and C₁₋₃ alkyl; or
R¹³ and R¹¹ are taken together with the moieties to which they are attached to form a 4- to 9-membered lactam;
R¹² is selected from NR¹³R¹⁴ and —(OCH₂CH₂)ₚ—OH;
R¹³ and R¹⁴ are independently selected from hydrogen and C₁₋₃ alkyl;
L¹ and L² are independently selected from divalent alkyl, divalent alkylether, divalent alkylamine, divalent alkylamide and divalent alkylester linker groups;
n is 1 to 20; and
p is 2 to 20.

In an embodiment, there is provided a microgel comprising a co-polymer of monomers (I) and (II), as described herein, wherein Y is:

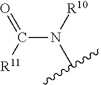

and optionally R¹⁰ and R¹¹ are both hydrogen.

In an embodiment monomer (I) is:

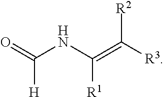

In an embodiment monomer (I) is:

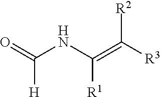

and R¹, R² and R³ are hydrogen.

In an embodiment, there is provided a microgel comprising a co-polymer of monomers (I) and (II), as described herein, wherein Y is:

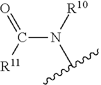

and R¹⁰ and R¹¹ are taken together with the moieties to which they are attached to form a 4- to 9-membered lactam.

In an embodiment monomer (I) is:

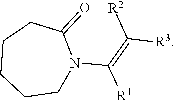

In an embodiment monomer (I) is:

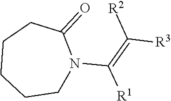

and R¹, R² and R³ are hydrogen.

In an embodiment, there is provided a microgel comprising a co-polymer of monomers (I) and (II), as described herein, wherein Y is:

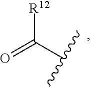

and optionally R¹² is NR¹³R¹⁴. In a preferred embodiment R¹³ and R¹⁴ are both hydrogen. In a preferred embodiment R¹³ is hydrogen and R¹⁴ is isopropyl.

In an embodiment monomer (I) is:

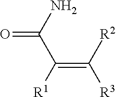

and R¹, R² and R³ are hydrogen.

In an embodiment monomer (I) is:

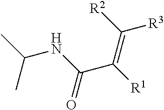

and R¹, R² and R³ are hydrogen.

In an embodiment monomer (I) is:

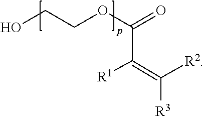

In an embodiment monomer (I) is:

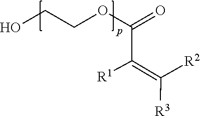

and R¹ is methyl and R² and R³ are hydrogen.

In an embodiment, there is provided a microgel comprising a co-polymer of monomers (I) and (II), as described herein, wherein Z is selected from:

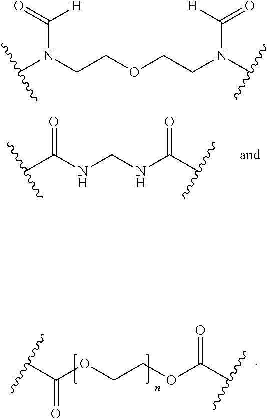

In an embodiment, Z is:

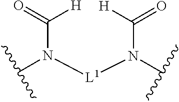

and L¹ is selected from divalent alkyl, divalent alkylether, divalent alkylamine, divalent alkylamide and divalent alkylester linker groups.

As used herein ‘divalent alkyl’ group refers to a branched or unbranched, optionally substituted 1 to 20 carbon alkylene linker. Examples of suitable divalent alkyl groups include methylene (CH₂) ethylene (CH₂CH₂), propylene or butylene.

As used herein ‘divalent alkylether’ group refers to a branched or unbranched, optionally substituted 1 to 20 carbon alkylene linker wherein one or more carbon atoms have been replaced by oxygen atoms. Examples of suitable divalent alkylether groups include —CH₂OCH₂—, —CH₂CH₂OCH₂CH₂—, —CH₂OCH₂CH₂— and —CH₂OCH₂CH₂OCH₂—.

As used herein ‘divalent alkylamine’ group refers to a branched or unbranched, optionally substituted 1 to 20 carbon alkylene linker wherein one or more carbon atoms have been replaced by nitrogen atoms. Examples of suitable divalent alkylamine groups include —CH₂NHCH₂—, —CH₂CH₂NHCH₂CH₂—, —CH₂NHCH₂CH₂— and —CH₂NHCH₂CH₂NHCH₂—. The N atoms may be optionally substituted with C₁₋₃alkyl groups.

As used herein ‘divalent alkylamide’ group refers to a branched or unbranched, optionally substituted 1 to 20 carbon alkylene linker wherein one or more carbon atoms have been replaced by amide moieties (—NHC(O)— or —C(O)NH—). Examples of suitable divalent alkylamide groups include —CH₂—C(O)NH—CH₂—, —CH₂CH₂—C(O)NH—CH₂CH₂— and —CH₂—NHC(O)CH₂CH₂—. The N atoms may be optionally substituted with C₁₋₃alkyl groups.

As used herein ‘divalent alkylester’ group refers to a branched or unbranched, optionally substituted 1 to 20 carbon alkylene linker wherein one or more carbon atoms have been replaced by ester moieties (—OC(O)— or —C(O)O—). Examples of suitable divalent alkylester groups include —CH₂—C(O)O—CH₂—, —CH₂CH₂—C(O)O—CH₂CH₂— and —CH₂—OC(O)CH₂CH₂—.

In an embodiment, Z is:

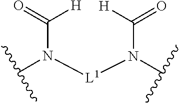

and L¹ is a divalent alkyl or divalent alkylether linker group, preferably L¹ is a divalent alkylether linker group.

In an embodiment, Z is

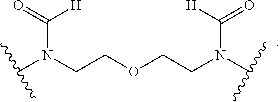 [SMILES: *N(C=O)CCOCCN(*)C=O]

In an embodiment monomer (II) is:

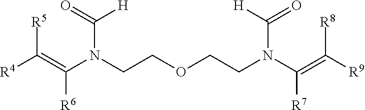

and R⁴, R⁵, R⁶, R⁷, R⁸ and R⁹ are hydrogen.

In an embodiment, there is provided a microgel comprising a co-polymer of monomers (I) and (II), as described herein, wherein Z is:

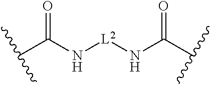

and L² is selected from divalent alkyl, divalent alkylether, divalent alkylamine, divalent alkylamide and divalent alkylester linker groups.

In an embodiment, Z is:

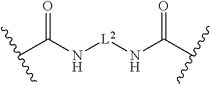

and L² is a divalent alkyl or divalent alkylether linker group, preferably L¹ is a divalent alkyl linker group.

In an embodiment, there is provided a microgel comprising a co-polymer of monomers (I) and (II), as described herein, wherein Z is:

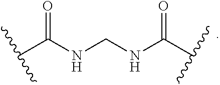 [SMILES: *C(=O)NCNC(*)=O]

In an embodiment monomer (II) is:

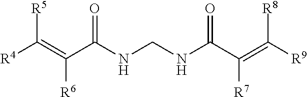

and R⁴, R⁵, R⁶, R⁷, Wand Ware hydrogen.

In an embodiment, Z is:

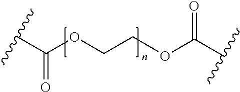

and n is 1 to 20, such as 1-5, or preferably n is 1.

In an embodiment monomer (II) is:

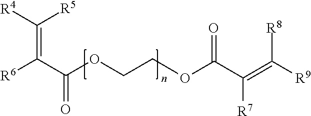

and R⁴, R⁵, R⁸ and R⁹ are hydrogen and R⁶ and R⁷ are methyl.

In an embodiment, the microgel particles comprise a co-polymer of:

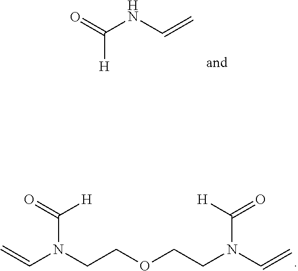

This co-polymer is poly(N-vinylformamide-co-2-(N-vinylformamido)ethyl ether) (PNVF-NVEE).

In an embodiment, the microgel particles comprise a co-polymer of:

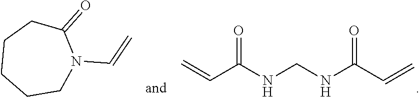

This co-polymer is poly(N-vinylcaprolactam-co-N,N′-methylenebis(acrylamide)) (PNVC-BA).

In an embodiment, the microgel particles comprise a co-polymer of:

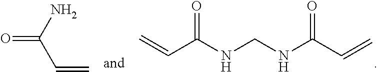

This co-polymer is poly(acrylamide-co-N,N′-methylenebis(acrylamide)) (PA-BA).

In an embodiment, the microgel particles comprise a co-polymer of:

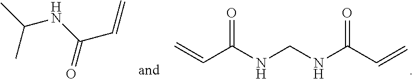

This co-polymer is poly(N-isopropylacrylamide-co-N,N′-methylenebis(acrylamide)) (PNIPAM-BA).

In an embodiment, the microgel particles comprise a co-polymer of:

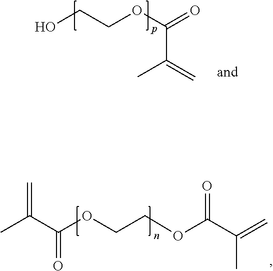

wherein n and p are as defined herein. This co-polymer is poly(polyethylene glycol methacrylate-co-polyethylene glycol dimethacrylate) (PPEGMA-PEDGMA).

The micropatterning approach of the present invention uses microgels as pore-forming particles to produce porous perovskite films. Therefore, the average pore size in the photoactive layer is influenced by the average diameter of the swollen (e.g. swollen from a ‘good’ swelling solvent such as DMSO) microgel particles after layer deposition. In an embodiment, the microgel particles as described herein have a diameter after swelling in the range 0.1 to 5 μm (100 to 5000 nm), more preferably in the range 0.1 to 1.5 μm (100 to 1500 nm), even more preferably in the range 400 to 1200 nm. In an embodiment, the microgel particles as described herein have a diameter after swelling in the range 750 to 1500 nm, more preferably in the range 900 to 1200 nm.

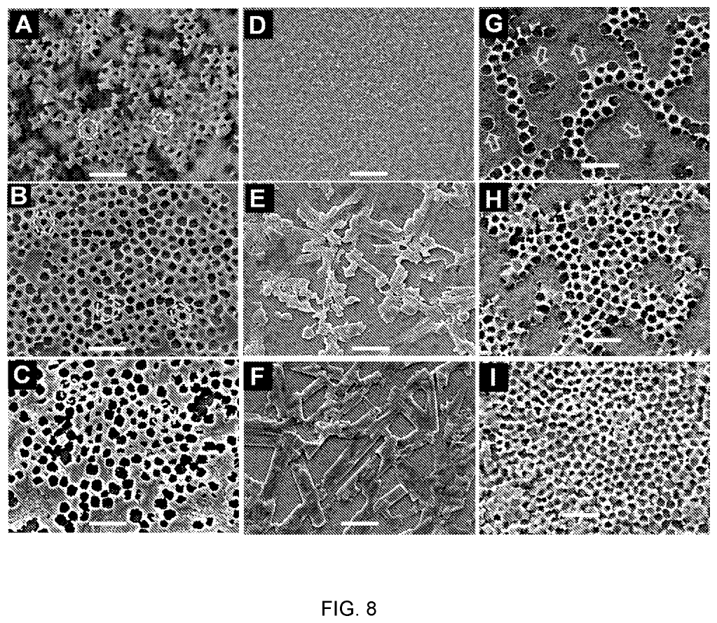

When a layer of microgel particles are deposited from a thermodynamically good solvent they tend to flatten. This can be seen in FIG. 1C where PNVF-NVEE MGs were deposited from DMSO and subsequently were measured with an average diameter of approximately 1200 nm and an average height of approximately 400 nm, indicating particle flattening after deposition. After deposition the microgel particles tend to form close-packed arrangements. In FIG. 1A, an SEM image of PNVF-NVEE MGs deposited from DMSO demonstrates their tendency to form hexagonally close-packed clusters. This same arrangement is seen for the photoactive perovskite layers formed in the presence of the microgel particles indicating the micropatterning effect of the MGs. In FIG. 8 SEM images of (CH₃NH₃⁺)(Pb²⁺)(I⁻)_{3-z}(Cl⁻)_{z} (hereafter referred to as MP) perovskite layers formed in the presence of PNVF-NVEE MGs—A to C and G to I—demonstrate the hexagonal close-packed arrangement of pores, whereas the layers formed in the absence of MGs—D to F—have no such arrangement.

In an embodiment, in a porous photoactive layer as described herein, the pores in the layer coincide with the location of the microgel particles.

In an embodiment, a porous photoactive layer as described herein, has an average pore size in the range 100-5000 nm, such as 100-1500 nm, preferably 500-1500 nm, more preferably 500-1200 nm, such as 700-1100 nm, or 800-1000 nm. In an embodiment, a porous photoactive layer as described herein, has an average pore size in the range 400-700 nm, or 300-600 nm. A porous photoactive layer with an average pore size in the range 300-700 nm, may allow photoactive layers to be prepared which are coloured, due to scattering of visible light by the pores.

The micropatterning effect of the MGs typically produces porous perovskite layers with disordered inverse opal (DIO) morphology, as shown in FIG. 8. In an embodiment, in a porous photoactive layer as described herein, the porous photoactive layer has a disordered inverse opal morphology.

It is desirable, in terms of the photoactive properties of the deposited layer and of solar cells constructed therefrom, that the DIO morphology covers the photoactive layer surface in a substantially continuous DIO film. In an embodiment, the porous photoactive layer has a disordered inverse opal morphology which covers greater than 60% of the photoactive layer surface. In a preferred embodiment, the porous photoactive layer has a disordered inverse opal morphology which covers greater than 70% of the photoactive layer surface, greater than 75% of the photoactive layer surface, more preferably greater than 80% of the photoactive layer surface, most preferably greater than 90% of the photoactive layer surface. In an embodiment, the porous photoactive layer has a disordered inverse opal morphology which covers the photoactive layer in a substantially continuous DIO film. In an embodiment, the porous photoactive layer has a disordered inverse opal morphology with substantially no voids in the DIO film. Voids refers to regions of the layer which do not possess DIO morphology. In an embodiment, the porous photoactive layer has a disordered inverse opal morphology with substantially no areas of perovskite in the DIO film. Areas of perovskite refers to non-porous regions of the layer, i.e. areas where microgel particles have not formed pores.

In an embodiment, the porous photoactive layer comprises 600 to 1200 nm pores and has a disordered inverse opal morphology which covers greater than 60% of the photoactive layer surface. In an embodiment, the porous photoactive layer comprises 700 to 1100 nm pores and has a disordered inverse opal morphology which covers greater than 70% of the photoactive layer surface. In an embodiment, the porous photoactive layer comprises 800 to 1000 nm pores and has a disordered inverse opal morphology which covers greater than 80% of the photoactive layer surface.

### Formation of Porous Perovskite Layers

In an aspect of the present invention, there is provided a method of forming a porous photoactive layer as described herein, comprising the steps of:
a) swelling particles of the microgel in a solvent to 1.2-100 times the size of the unswollen particles;
b) adding hybrid inorganic-organic perovskite precursors to the dispersion of swollen microgel particles from step a);
c) coating the dispersion from step b) onto a substrate; and
d) evaporating the solvent.

In step a) microgel particles as described herein, are swollen in a thermodynamically ‘good’ solvent for the microgels. A suitable solvent will swell the particles to 1.2-100 times the size of the unswollen particles. In an embodiment, the linear swelling ratio of the microgel particles is in the range 1.2 to 100. In an embodiment, in step a) the particles are swollen to 1.2-50 times, such as 1.2-25, 1.2-10 or 1.2-5 times the size of the unswollen particles. In an embodiment, the linear swelling ratio of the microgel particles is in the range 1.2 to 50, such as 1.2 to 25, 1.2 to 10, or 1.2 to 5. In an alternative embodiment, step a) comprises swelling particles of the microgel in a solvent to 1.5-10 times the volume (this is the volume swelling ratio) of the unswollen particles. Preferably, the volume swelling ratio of the microgel particles is between 1.5 and 5, between 1.5 and 3, or between 2 and 3, compared to the unswollen particles. A suitable solvent comprises polar aprotic solvents. In an embodiment, the solvent is selected from γ-butyrolactone, dimethyl formamide, dimethyl sulfoxide, or a combination of these solvents. In a preferred embodiment, the solvent is dimethyl sulfoxide. In an embodiment, the solvent in step a) comprises polar aprotic solvents or water, or a mixture thereof.

In step b) hybrid inorganic-organic perovskite precursors are added to the dispersion of swollen microgel particles from step a), so that after deposition the hybrid inorganic-organic perovskite crystallises on the substrate. The hybrid inorganic-organic perovskite precursors are compounds which, when combined, are capable of forming a hybrid inorganic-organic perovskite of formula ABX₃, as defined herein. In a preferred embodiment, the precursors are of the formula AX and BX₂, wherein A, B and X are as defined herein. For example, the perovskite precursors may be C₁₋₆alkyl-NH₃X and PbX₂, such as CH₃NH₃X and PbX₂ (for example, CH₃NH₃I and PbCl₂).

In a preferred embodiment, steps a) and b) are carried out concurrently. In other words, the microgel particles and the perovskite precursors, are dispersed in a suitable solvent (such as a polar aprotic solvent), in a single step.

Step c) involves deposition of the perovskite precursor/microgel dispersion onto a substrate. A suitable substrate for forming the porous photoactive layer on, is any layer which may be conventionally used in the production of solar cells and which is stable to the solvent used in step a). Preferably, the substrate is a mesoporous TiO₂ layer.

A skilled person may envisage various deposition methods suitable for achieving the coating in step c). Such methods may include casting, doctor blading, screen printing, inkjet printing, pad printing, knife coating, meniscus coating, slot die coating, gravure coating, reverse gravure coating, kiss coating, micro-roll coating, roll-to-roll coating, curtain coating, slide coating, spin coating, spray coating, flexographic printing, offset printing, rotatory screen printing, evaporative coating or dip coating. In a preferred embodiment, the coating in step c) is carried out by spin coating.

In step d) the solvent is evaporated, either passively (under ambient conditions) or actively (e.g. via the application of heat and/or vacuum to the coated dispersion). Solvent evaporation drives crystallization of the hybrid inorganic-organic perovskite. To enhance perovskite crystallization, an anti-solvent may be added during the coating or evaporating steps. In an embodiment, step c further comprises the addition of an anti-solvent during coating. Preferably the anti-solvent is added at or towards the end of the coating step. An anti-solvent is defined as a solvent in which the hybrid inorganic-organic perovskite, as described herein, has poor solubility. In an embodiment, the anti-solvent is selected from chlorobenzene, benzene, xylene, toluene, methanol, ethanol, ethylene glycol, 2-propanol, chloroform, THF, acetonitrile, and benzonitrile, or a combination thereof. In a preferred embodiment, the anti-solvent is toluene.

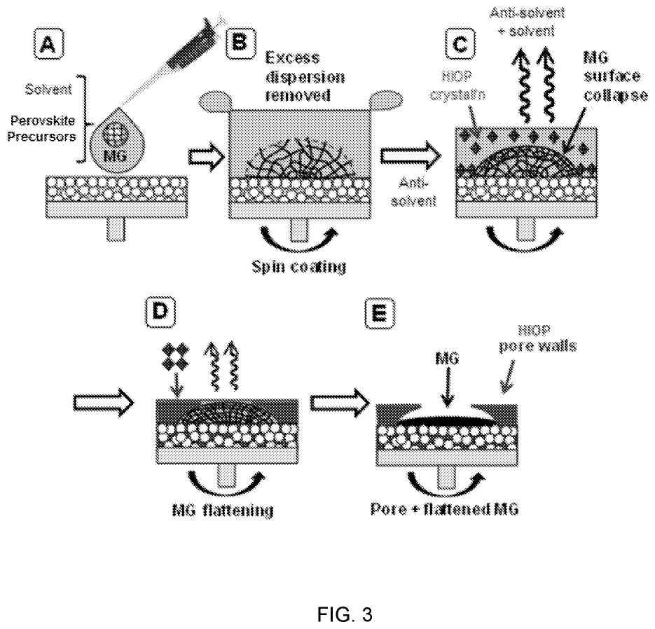

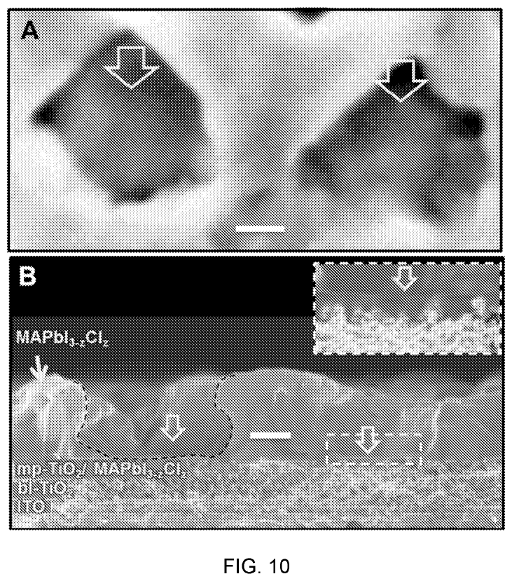

FIG. 3 shows a schematic representation of a proposed mechanism by which the porous perovskite layers of the present invention are formed. Crystallised hybrid inorganic-organic perovskite (HIOP) forms around the swollen microgel (MG) particles. As the solvent evaporates and the crystallization progresses, the MG also collapses to leave flattened microgel in the bottom of a pore in the perovskite layer. The relatively slow MG collapse results in the formation of the DIO film, with the pore-size related to the size of the originally deposited MGs. The high magnification SEM images of two pores shown in FIG. 10 provide evidence to support this mechanism; the large white arrows highlight the flattened MGs.

The DIO coverage of the photoactive layer surface can be influenced by the concentrations of both the microgel and the hybrid inorganic-organic perovskite precursors. In an embodiment, in step a) the microgel particles are at a concentration (C_{MG}) of 1-10% w/w. In an embodiment, in step a) the microgel particles are at a concentration (C_{MG}) of 1.5-7% w/w. In an embodiment, in step a) the microgel particles are at a concentration (C_{MG}) of 2-5% w/w. In an embodiment, in step b) the HIOP precursors are at a concentration (C_{MP}) of 20-60% w/w. In an embodiment, in step b) the HIOP precursors are at a concentration (C_{MP}) of 25-50% w/w. In an embodiment, in step a) the microgel particles are at a concentration (C_{MG}) of 1-10% w/w, and in step b) the HIOP precursors are at a concentration (C_{MP}) of 15-70% w/w. In an embodiment, in step a) the microgel particles are at a concentration (C_{MG}) of 1.5-7% w/w, and in step b) the HIOP precursors are at a concentration (C_{MP}) of 20-60% w/w. In an embodiment, in step a) the microgel particles are at a concentration (C_{MG}) of 2-5% w/w, and in step b) the HIOP precursors are at a concentration (C_{MP}) of 25-50% w/w.

In a further aspect, there is provided a porous photoactive layer directly obtained by, obtained by, or obtainable by a method as described herein.

### Properties of the Porous Perovskite Layers

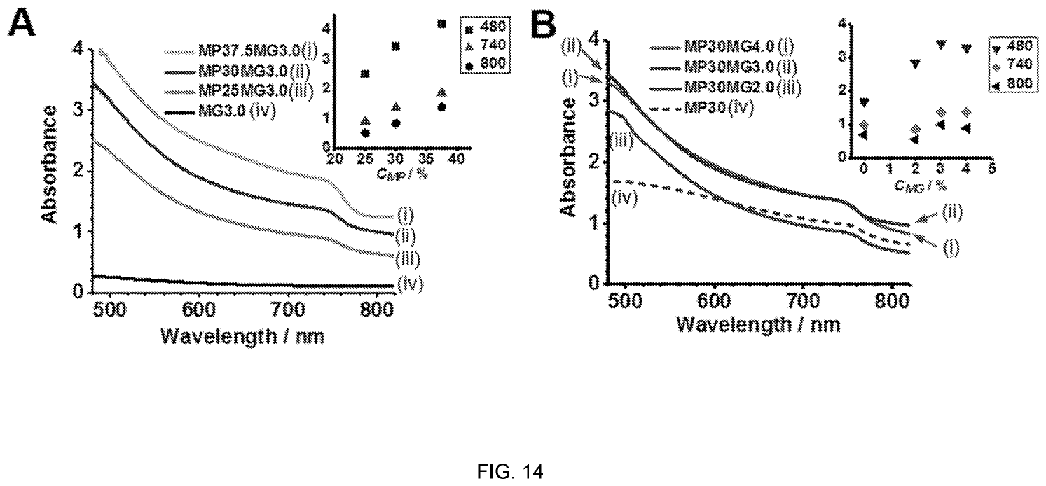

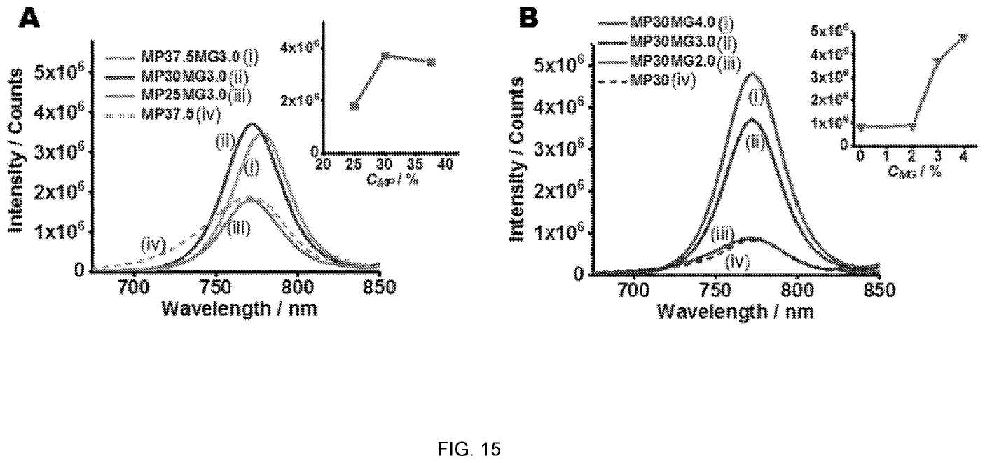

As already discussed, the porous perovskite layers of the present invention typically have DIO morphology. Due to their strong light scattering and tunable reflectivity, DIO films are of interest for enhancing solar cell performance. As expected, with increasing HIOP concentration, an increase in absorbance of UV-visible light is observed (FIG. 14A). At a given HIOP concentration, however, higher MG concentrations increase the light absorption across the whole UV-visible spectrum (FIG. 14B). Furthermore, photoluminescence (PL) intensity of the perovskite layer increases on formation of substantial DIO morphology via MG micropatterning (FIG. 15). A high PL intensity indicates decreased quenching is occurring. As the thickness of the capping layer increases more of the HIOP is located further from the mesoporous-TiO₂ substrate and is less able to be quenched. Accordingly, it is suggested that the increased PL intensity for the layers, is a result of the increased capping layer thickness caused by the MG particle micropatterning. For the avoidance of doubt, the capping layer refers to the DIO HIOP film that sits on top of the mp-TiO₂ layer. The mp-TiO₂ layer also contains HIOP after deposition of the HIOP dispersion, due to its mesoporous nature. Therefore, both the DIO HIOP film (capping layer) and the mp-TiO₂ layer are photoactive. In an embodiment, a porous photoactive layer as described herein, has a capping layer thickness of 100-1000 nm. Preferably, the capping layer thickness is 400-1000 nm, such as 600-1000 nm.

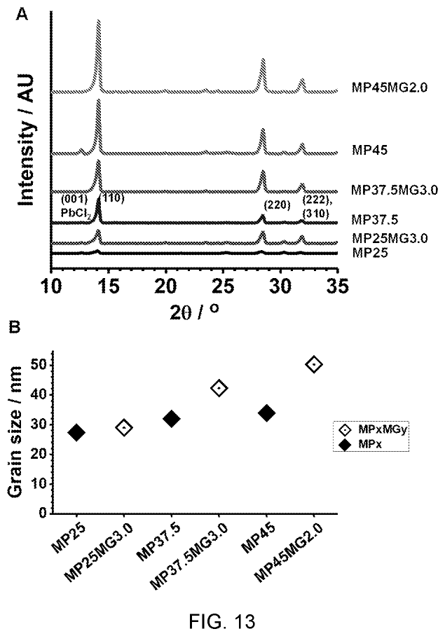

In comparison to MG-free perovskite layers, the HIOP grain size is increased in layers prepared according to the present invention, at the same concentration of HIOP precursors (FIG. 13B). Larger grains of crystallised HIOP may be beneficial for photo-charge transport across the photoactive layer. In an embodiment, a porous photoactive layer as described herein, comprises HIOP with an average grain size greater than 35 nm, preferably greater than 40 nm. The average grain size can be determined from the application of the Scherrer equation to the HIOP XRD peaks (Jeong et al., ACS Nano, 2016, 10, 9026-9035; Langford et al., J. Appl. Cryst, 1978, 11, 102-113).

Porous photoactive layers prepared according to the present invention may also demonstrate increased HIOP conversion. Conversion refers to the % of HIOP produced by the reaction of the precursor perovskite species.

### Perovskite Solar Cells

PSCs can be constructed comprising porous photoactive layers according to the present invention. Therefore, in an aspect of the invention, there is provided a perovskite solar cell comprising a porous photoactive layer as described herein.

Perovskite solar cells may be constructed using processes and techniques familiar to those in the field. A PSC is typically formed from a number of layers selected from one or more of glass, indium tin oxide (ITO), TiO₂ hole-blocking layer (bl-TiO₂), mesoporous TiO₂ layer (mp-TiO₂), perovskite photoactive layer (capping layer), hole transport layer and gold. Preferably, the PSC layers are deposited on top of one another in the order glass, ITO, TiO₂ hole-blocking layer (bl-TiO₂), mesoporous TiO₂ layer (mp-TiO₂), perovskite photoactive layer, hole transport layer and gold. In PSCs comprising porous photoactive layers according to the present invention, the porous photoactive layer is the perovskite photoactive layer (capping layer).

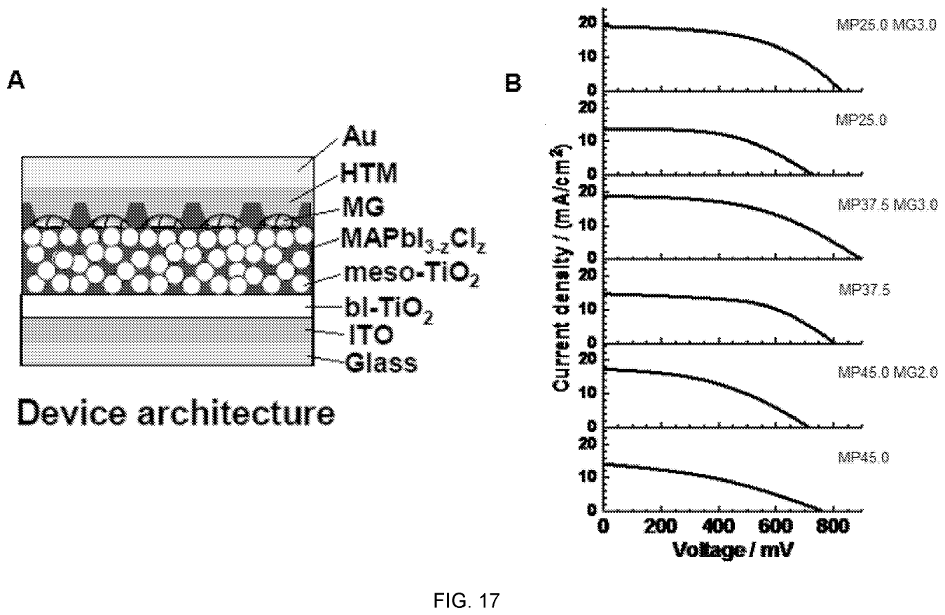

A process for forming a PSC may comprise coating the HIOP-MG dispersion onto a glass/ITO/bl-TiO₂/mp-TiO₂ substrate, and then applying a hole transport layer, followed by a gold coating (see FIG. 17A for a schematic of the solar cell architecture).

PSCs formed with porous photoactive layers according to the present invention may have significantly higher short-circuit current density (J_{sc}) values compared to analogous PSCs prepared with non-porous photoactive layers. Increased light harvesting by the porous photoactive layers as described herein, due to their increased capping layer thickness, may be contributing to the superior J_{sc} values.

PSCs formed with porous photoactive layers according to the present invention may have significantly higher power conversion efficiency (PCE) values compared to analogous PSCs prepared with non-porous photoactive layers. It is postulated that the collapsed microgel particles located in the pores sitting on top of the mp-TiO₂ layer, act as insulation between the hole transport layer and the mp-TiO₂ thus preventing short-circuits which decrease the PCE. The superior PCEs are also attributable to the increased J_{sc} values.

Throughout the description and claims of this specification, the words “comprise” and “contain” and variations of them mean “including but not limited to”, and they are not intended to (and do not) exclude other moieties, additives, components, integers or steps. Throughout the description and claims of this specification, the singular encompasses the plural unless the context otherwise requires. In particular, where the indefinite article is used, the specification is to be understood as contemplating plurality as well as singularity, unless the context requires otherwise.

### Examples

The invention will now be described in more detail in relation to the following illustrative examples.

### Physical Measurements

Unless stated otherwise, the following methodology was used to obtain physical measurements.

Dynamic light scattering (DLS) measurements was obtained using a Malvern Zetasizer Nano ZS instrument (via cumulants analysis). The z-average diameter (d_{z}) is an average value from five runs.

Optical microscopy was conducted using an Olympus BX41 microscope. Fractional coverage values were calculated using Image J software.

The top view SEM was obtained using a Philips XL30 FEGSEM and the cross-section SEM was obtained using a Carl Zeiss Sigma FESEM. The samples were coated with Au or Pd.

AFM images were obtained using an Asylum Research MFP-3D operating in AC (“tapping”) mode.

UV-visible spectra were recorded using a Perkin Elmer Lamda 25 UV-Vis spectrometer. The average visible transmittance was measured between 370 and 740 nm.

Film thickness measurements were conducted using a Dektak 8 Stylus Profilometer (Bruker).

XRD patterns were conducted using a Bruker D8 Advance diffractometer (Cu-Kα). Films were scanned with a step size of 0.02°. The films were prepared under nitrogen atmosphere and measured using an airtight holder.

Photoluminescence (PL) spectra were obtained using an Edinburgh Instruments FLS980 spectrometer. The beam was incident on the film surface side and an excitation wavelength of 480 nm was used.

### Device Measurements

Unless stated otherwise, the following methodology was used to obtain device measurements.

The current density-voltage (J-V) characteristics were measured using a Keithley 2420 Sourcemeter and 100mWcm² illumination (AM 1.5G) and a calibrated NREL certified Oriel Si-reference cell. An Oriel solar simulator (SOL3A) was used for these measurements. The active area of the devices (0.025 cm²) was determined using a square aperture within a mask. The data shown are from the reverse scan unless otherwise stated (V_{oc} to J_{sc}) and the sweep rate was 100 mV s⁻¹.

### Materials

N-vinylformamide (NVF, 98%), azoisobutyronitrile (AIBN, 98%), potassium-tert-butoxide (95%), bis(2-bromoethyl)ether (BBE, 95%), dicyclohexyl-18-crown-6 (98%), anhydrous tetrahydrofuran (THF, 99.9%), and ethanol (99.9%), poly(l-vinylpyrrolidone-co-vinyl acetate) (PVP-co-PVA, Mₙ˜50,000 g/mol), anhydrous sodium sulphate (100%), chloroform (99.9%), sodium chloride (NaCl, 100%), toluene (99.8%), chlorobenzene (CBZ, 99.8%), isopropanol (IPA, anhydrous, 99.5%), 4-tert-butylpyridine (TBP, 96%) and lithium bistrifluoromethanesulfonimidate (LiTFSI, 99.95%) were all purchased from Aldrich and used as received. Methyl amine solution (33 wt. % in absolute EtOH) and hydroiodic acid (57 wt. %), titanium diisopropoxide bis(acetylacetonate) (TDB, 75 wt % in IPA), lead (II) chloride (PbCl₂, 98%) and dimethyl sulfoxide (DMSO, 99.7%) were also purchased from Aldrich and used as received. Methylammonium iodide (MAI) was synthesised and purified using the method previously reported (Etgar et al., J. Amer. Chem. Soc., 2012, 134, 17396-17399). Titania paste (TiO₂, 18 NRT) was purchased from Dyesol and used as received. Spiro-MeOTAD (Spiro, N²,N²,N^{2′},N^{2′},N⁷,N⁷,N^{7′},N^{7′}-octakis(4-methoxyphenyl)-9,9′-spirobi[9H-fluorene]-2,2′,7,7′-tetramine, Fenglin Chemicals, 99.5%) was also used as received. Water was of ultra-high purity and de-ionised.

Method 1—Preparation of 2-(N-vinylformamido)ethyl ether (NVEE)

NVEE was synthesized in a 250 mL reactor equipped with an overhead stirrer. Firstly, a mixture of NVF (7.1 g, 100 mmol), potassium-tert-butoxide (12 g, 105 mmol) and dicyclohexyl-18-crown-6 (1 g, 2.65 mmol) were dissolved in anhydrous THF (100 mL). Then this mixture was stirred vigorously at room temperature for 45 min and was cooled to 0° C. in an ice bath for 20 min. Bis(2-bromoethyl)ether (9.3 g, 40 mmol) was then added dropwise to the mixture during cooling and the mixture was stirred at room temp for 72 h. After that, KBr was removed from the mixture by filtration and the reaction mixture was concentrated under rotary evaporator and diluted with water (100 mL). The product was repeatedly extracted with chloroform (5×40 mL) and washed twice with brine and then dried over anhydrous sodium sulphate (40 g) for 24 h. Finally, the product was recovered as a liquid after concentration using rotary evaporation.

Method 2—Preparation of poly(NVF-co-NVEE) [PNVF-9NVEE] Microgel Particles

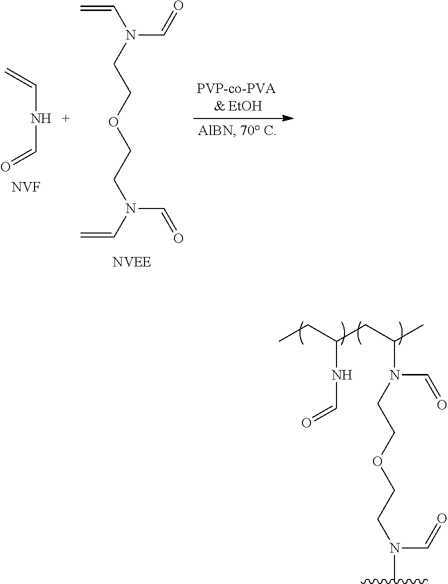

NVF-9NVEE microgel particles were prepared by non-aqueous dispersion polymerization. The MGs nominally contained 9.0 wt % NVEE based on monomer. A mixture of NVF (6.0 g, 85.5 mmol), PVP-co-PVA (1.8 g) and NVEE (1.79 g, 8.28 mmol) were added to EtOH (86 mL) in a four-necked round bottomed flask equipped with overhead stirrer, nitrogen supply and a reflux condenser. The solution was heated to 70° C. and stirred vigorously. Then, AIBN (0.240 g, 1.45 mmol) in EtOH (2.0 mL) was added to the reactor flask and the polymerization allowed to continue for 1 h. The dispersion was filtered with a 50 μm mesh filter after cooling to 0° C. and was then purified by three centrifugation and re-dispersion steps in EtOH.

The MGs prepared according to Method 2, when deposited from ethanol and DMSO, had z-average diameters (d_{z}) of 885 nm (PDI=0.013) and 1125 nm (PDI=0.088) respectively, as measured by dynamic light scattering (FIG. 1B). The volume swelling ratio for the MG particles is estimated as 2.1 from these d_{z} values.

Method 3—Preparation of poly(NVF-co-NVEE) [PNVF-9NVEE] Sub-Micrometer Microgel Particles

NVF-9NVEE sub-micrometer microgel particles were prepared by non-aqueous dispersion polymerization. The MGs nominally contained 9.0 wt % NVEE based on monomer. A mixture of NVF (3.0 g, 42.75 mmol), PVP-co-PVA (1.8 g) and NVEE (0.9 g, 4.16 mmol) were added to EtOH in a four-necked round bottomed flask equipped with overhead stirrer, nitrogen supply and a reflux condenser. The solution was heated to 70° C. and stirred vigorously. Then, AIBN (0.12 g, 0.73 mmol) in EtOH (2.0 mL) was added to the reaction flask and the polymerization allowed to continue for 1 h. The dispersion was filtered with a 50 μm mesh filter after cooling to 0° C. and was then purified by three centrifugation and re-dispersion steps in EtOH.

The MGs prepared according to Method 3, when deposited from ethanol and DMSO, had z-average diameters (d_{z}) of 354 nm (PDI=0.012) and 495 nm (PDI=0.041) respectively, as measured by dynamic light scattering (FIG. 1D). By decreasing the total mass of monomers used in the MG synthesis by a factor of two, the MG diameters have decreased by more than a factor of two. The volume swelling ratio for the MG particles is estimated as 2.7 from these d_{z} values.

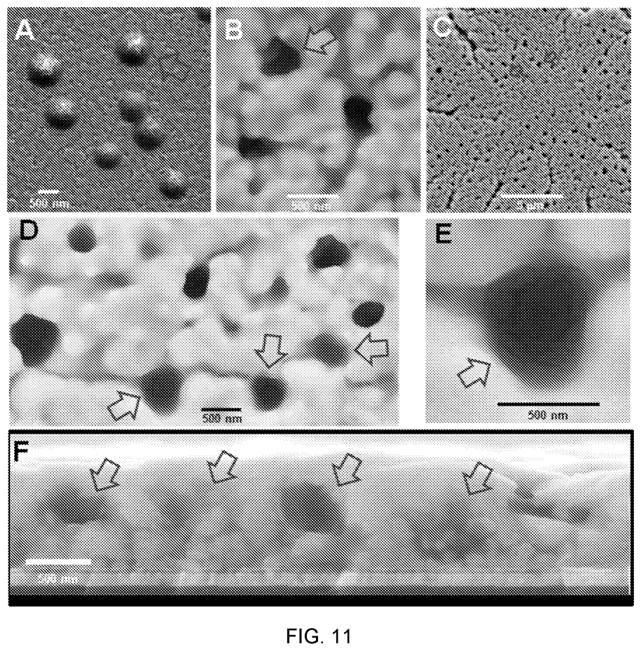

The MGs exhibited low polydispersity as shown by TEM images (e.g. FIG. 11A). The MGs deposited from ethanol (FIG. 1E) were spherical and had a number-average diameter of 336 nm when measured using SEM. The MGs deposited from DMSO (FIG. 1F) had a much larger diameter of 731 nm when measured using SEM. MGs are highly deformable and flatten when deposited from the swollen state.

### Method 4—Microgel Film Formation

NVF-9NVEE microgel particles as prepared in Methods 2 and 3 were dispersed in EtOH (‘poor’ solvent) and centrifuged at 7,000 rpm and then re-dispersed in DMSO (‘good’ solvent). Then, the centrifugation speed was increased to 10,000 rpm. Finally, the sedimented particles were re-dispersed in DMSO again. The MG particles were re-dispersed in DMSO at various concentrations from 1.0 to 7.0 wt %. The MG dispersion were rapidly added (dropwise) to a clean and dry glass slide and spin coated at 3,000 rpm for 15 s using a Laurell WS-650 Mz-23NPP spin processor for the films.

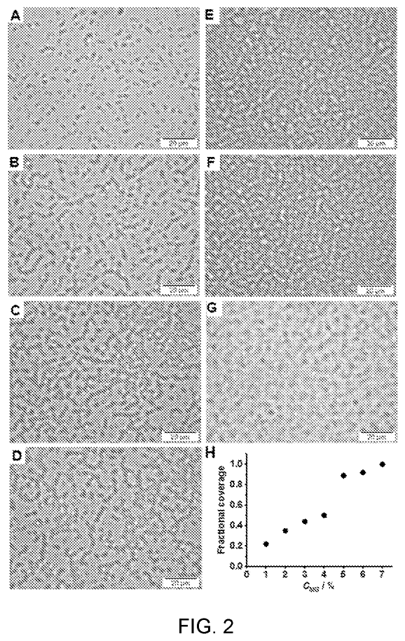

The optical micrographs of the deposited Method 2 MGₓ films are shown in FIG. 2. The ability of the MGs to cover a surface was probed by measuring the effect of C_{MG} on the fractional coverage. When C_{MG} was 5.0% there were few MG-free regions and full coverage occurred at C_{MG}=7.0 wt. %.

Method 5—Preparation of (CH₃NH₃⁺)(Pb²⁺)(I⁻)_{3-z}(Cl⁻)_{z} [MAPbl_{3-z}Cl_{z}]/MG Films

Indium tin oxide (ITO)-coated glass substrates (20 Ω/sq) were cleaned by ultrasonication in a 1.0 wt % Hellmanex solution, rinsed with water, IPA, NaOH (2.5 M), water again and dried. A TiO₂ hole blocking layer (bl-TiO₂) (60 nm) was spin-coated at 2000 rpm for 60 s onto the ITO using TDB solution in 1-butanol (0.15 M followed by 0.30 M) and subsequent heating at 125° C. for 5 min. After that, TiO₂ paste (1:5 in EtOH) was spin coated at 5000 rpm for 30 s onto the cleaned ITO substrate to form a mesoporous scaffold (mp-TiO₂). The mp-TiO₂ films (thickness ˜250 nm) were annealed at 500° C. for 30 min and cooled to room temperature. A MAPbl_{3-z}Cl_{z} with MGs precursor solution (100 μl)* was spin-coated onto the ITO/bl-TiO₂/mp-TiO₂ substrate at 4000 rpm for 25 s. During the spin coating process, toluene (500 μL) was dropped on the surface of film being fabricated in the last 15 s. The films were dried at 100° C. for 45 min. All films were stored in a desiccator over P₂O₅ in the dark until investigation. *The precursor solution contained MAI and PbCl₂ (3:1 molar ratio) to give MAPbl_{3-z}Cl_{z}. The solution also contained MGs in DMSO at various compositions. For example, in the MP37.5MG3.0 dispersion the precursor mixture/solution contained 37.5 wt. % of perovskite precursors [i.e., MAI and PbCl₂ (3:1 molar ratio)], 3.0 wt. % of MG and 59.5 wt. % of DMSO.

The perovskite/MG films are denoted in terms of the concentrations of MG (C_{MG}) and MAPbl_{3-z}Cl_{z} (C_{MP}) used to spin coat the film, i.e., MPxMGy. The MGs were first characterized and then the morphologies of the MPxMGy films were investigated.

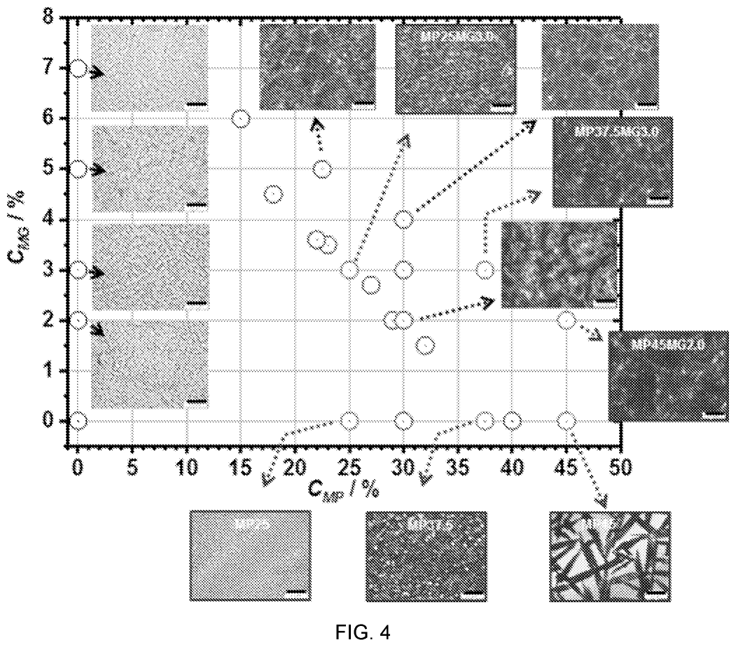

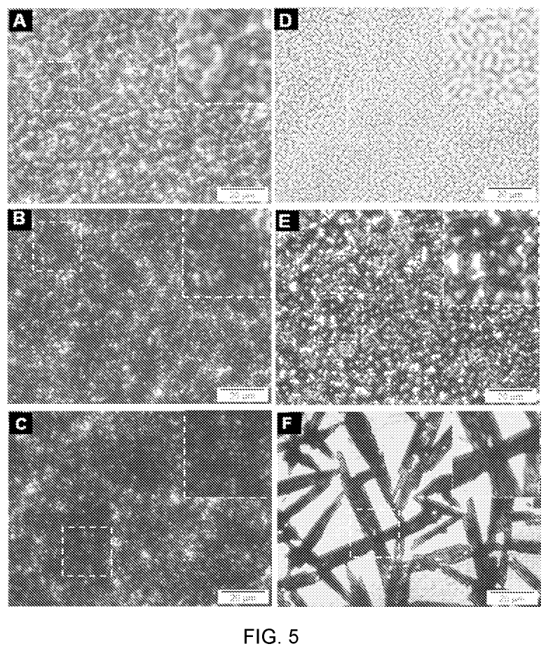

FIGS. 4 and 5 show optical micrographs obtained for the MPxMGy films using MGs prepared according to Method 2 (M2 MGs), which showed rich morphologies that were strongly dependent on C_{MG} and C_{MP}.

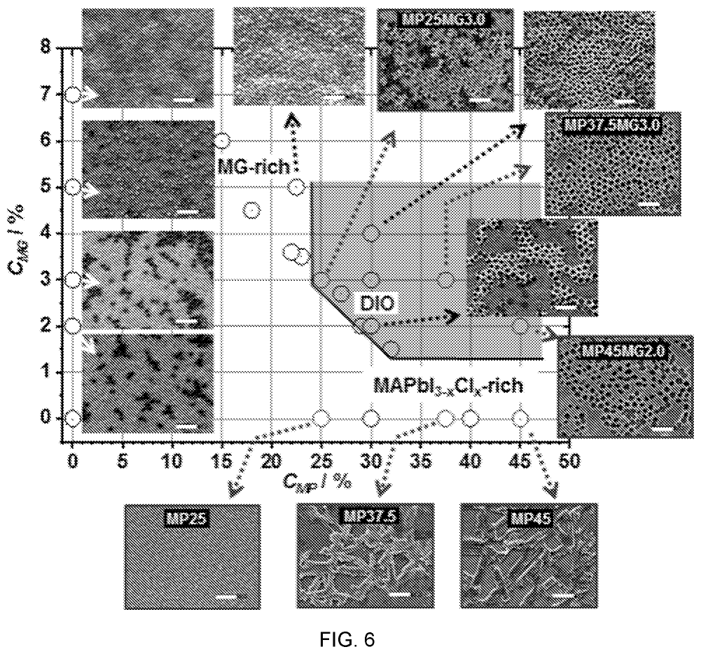

FIG. 6 shows a morphological phase diagram constructed from SEM images of the MPxMGy films prepared according to Method 5 using M2 MGs. The pure MG films (i.e. MGy) showed isolated MG clusters which became more uniform as C_{MG} increased (see vertical series with C_{MP}=0). The pure MAPbl_{3-z}Cl_{z} films (i.e. MPx) correspond to the horizontal sequence of images with C_{MG}=0. MP25 had an appearance similar to that of the mp-TiO₂ layer; whereas, MP37.5 and MP45 had large crystals within the capping layer as well as many pinholes. In contrast the MPxMGy films in the upper right-hand corner of the phase diagram had a remarkable DIO morphology. The DIO region is shaded in FIG. 6.

FIG. 8 shows SEM images obtained for nine of the MPxMGy films prepared according to Method 5 using M2 MGs. Several DIO film morphologies (FIGS. 8A, B and C) were compared to those for the MG-free systems (FIGS. 8D, E and F) at the same MPx concentration. These comparisons confirm that the MGs were responsible for the DIO morphology. There was also local hexagonal close packing of the pores (shown in FIGS. 8A, B and C). Such packing was present for deposited MGs (see FIG. 1A). This trend demonstrates that the MGs directed the pore morphology and acted as micropatterning additives. Increasing the MG concentration also increased DIO film coverage of the surface (see FIGS. 8G, H and I). An important observation from FIG. 8G is that the DIO perovskites formed in regions closely associated with the deposited MGs. This trend is highlighted with arrows for the SEM of the MP30MG2.0 film in FIG. 8G. Hence, there was an attractive interaction between the HIOP and the MG particles.

The average pore size for MPxMGy films (prepared according to Method 5 using M2 MGs) containing DIO morphologies were measured and are given in Table A.

TABLE A

| Film | Morphology description | Pore size/nm |
|---|---|---|
| MP30.0MG2.0 | Small DIO islands | 922 ± 83 |
| MP30.0MG3.0 | Large DIO islands | 866 ± 79 |
| MP30.0MG4.0 | Continuous DIO film | 812 ± 69 |
| MP25.0MG3.0 | DIO Clusters | 657 ± 87 |
| MP37.5MG3.0 | Continuous DIO film | 939 ± 63 |
| MP45MG2.0 | Continuous DIO film | 988 ± 60 |

The average pore size for the MP30MG2.0, MP30MG3.0 and MP30MG4.0 films decreases as C_{MG} increases. This decrease in size is due to closer packing (and compression) of the MGs during film deposition. Hence, the MG packing influenced the DIO pore size.

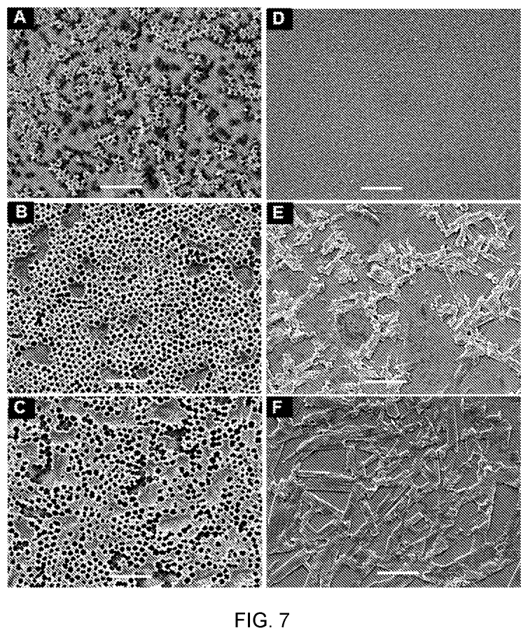

FIG. 7 shows a comparison of lower magnification SEM images for the MP25MG3.0, MP37.5MG3.0 and MP45MG2.0 films (prepared according to Method 5 using M2 MGs) compared to the respective MPx (i.e. MG-free) films. The inclusion of MGs within the films was observed to increase the amount of capping layer.

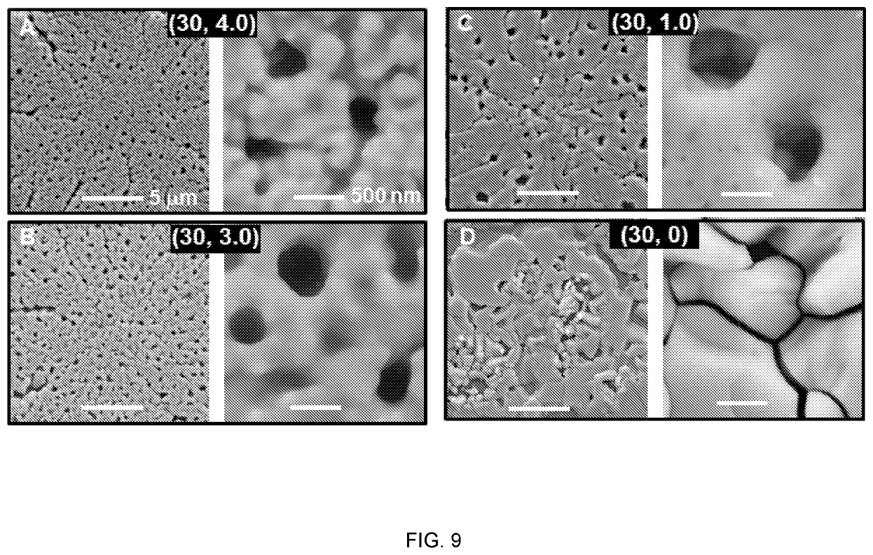

SEM images for MP30MGy films (prepared according to Method 5 using microgels prepared according to Method 3 (M3 MGs)) with y=0, 1, 3 and 4% are shown in FIG. 9. The average MG sizes for the MP30 films prepared using y=1.0, 3.0 and 4.0 were 542±75 nm, 454±65 and 342±73 nm, respectively. Comparing these diameters with those discussed above from SEM for the MGs deposited from DMSO (731 nm) and EtOH (336 nm) shows that the MGs were increasingly constrained laterally within the MP30MGy composite films as y increased.

FIG. 10A shows an SEM image measured for a MP37.5MG3.0 DIO film (prepared according to Method 5 using M2 MGs) and two pores can be seen with MGs within them. A cross-section for the film was prepared and examined by SEM (see FIG. 10B). Two pores were evident and flattened MG particles could be seen. The underlying mp-TiO₂ layer in the pore was covered by the MG, which would have prevented direct contact between hole transport material and mp-TiO₂ in devices. Furthermore, the walls between the pores appear to be uniform grains that extend from the top of the capping layer to the mp-TiO₂ layer, which should be beneficial for photo-charge transport.

FIGS. 11B and 11C show SEM images measured for MP30MG4.0 films (prepared according to Method 5 using M3 MGs) Black regions are evident (arrows), which are pores associated with MGs. This can be seen more clearly from the SEM images for the MP30MG3.0 film shown in FIGS. 11D and 11E. The latter figure has an appearance resembling a pool of melted ice.

FIG. 11F shows a SEM cross-sectional image for the MP30MG4.0 film (M3 MGs). The SEM image shows dark spherical structures in the interior of the film (arrows) that are buried, encapsulated MGs within the perovskite film. The presence of buried and surface MGs differs from the morphology seen in FIG. 10B where only surface pores were evident. This difference is because when using the sub-micrometer microgel particles prepared according to Method 3, the MG diameter was less than the film thickness.

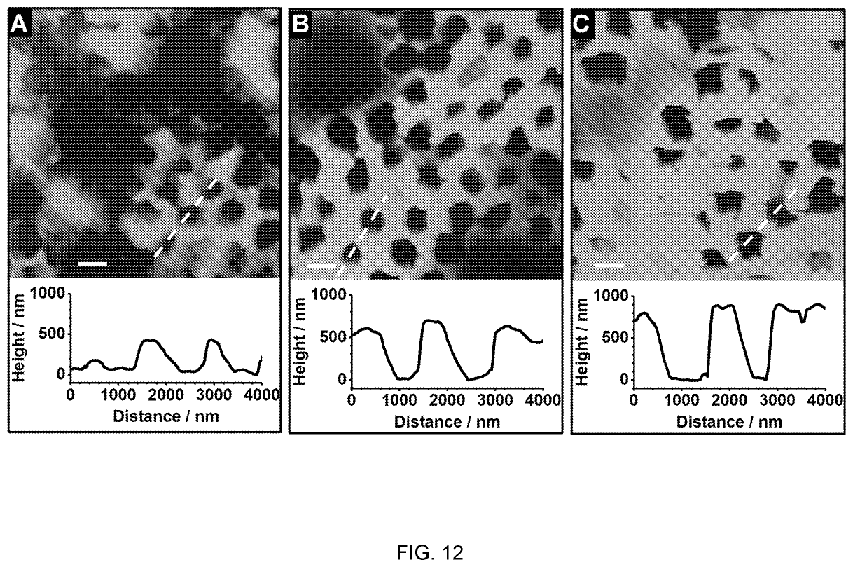

FIG. 12 shows AFM images for MP25MP3.0, MP37.5MG3.0 and MP45MG2.0 films (prepared according to Method 5 using M2 MGs) that show that the depth of the pores (and hence pore wall height and barrier layer thickness) clearly increased with increasing C_{MP}.

The effect of the MGs on the perovskite structure was investigated using XRD for M25MG3.0, MP37.5MG3.0 and MP45MG2.0 films (M2 MGs) as well as the respective MG-free films (see FIG. 13). These data clearly show that the intensity of the MAPbl_{3-z}Cl_{z} peaks increased and their breadth (full-width at half-maximum) decreased when MG was present (See FIG. 13A). The grain sizes for all of the films were calculated from the Scherrer equation (Jeong et al., ACS Nano, 2016, 10, 9026-9035; Langford et al., J. Appl. Cryst., 1978, 11, 102-113). The MGs increased the perovskite grain size for both the MP37.5MG3.0 and MP45MG2.0 films compared to the MG-free control films (See FIG. 13B). Furthermore, consideration of the PbCl₂ peak shows that the MGs unexpectedly increased MAPbl_{3-z}Cl_{z} conversion for all three films (see FIG. 13A). One possible explanation for this result is that the MGs forced more of the MAPbl_{3-z}Cl_{z} HIOP to form in the capping layer compared to the restrictive confines of the underlying mp-TiO₂ layer.

The light absorption properties of the films were assessed using UV-visible spectroscopy (see FIGS. 14A and B). The MG particles did not absorb light in the spectral range examined here as shown by the spectrum for MG3.0 in FIG. 14A. The UV-visible spectra for the MPxMG3.0 films (M2 MGs) in FIG. 14A show that increasing x (or C_{MP}) increased the absorbance as expected because there was more perovskite deposited. The inset shows that this trend was pronounced. The effect of C_{MG} on the UV-visible spectra was also studied (see FIG. 14B). Including MGs greatly increased the light absorbed by MAPbl_{3-z}Cl_{z} across the whole spectrum when y was greater than or equal to 2.0% (see inset). This occurred in part due to enhanced light scattering as can be seen from the strong absorbance at 800 nm. In addition, the quantity of MAPbl_{3-z}Cl_{z} increased within the films as a consequence of MG particles being added—which was indicated by the SEM images for these same films (see FIGS. 8G, H and I). It follows that the MG particles decreased the loss of MAPbl_{3-z}Cl_{z} solution during spin coating. It is postulated that the MGs reduced the flow of the solution during the coating process.

Photoluminescence (PL) spectra were measured for the films. The effect of x (or C_{MP}) was investigated for the MPxMG3.0 films (M2 MGs)—see FIG. 15A. The PL intensity reached a plateau when x=30, which corresponds to extensive DIO film formation (see FIG. 8H). The effect of C_{MG} (i.e., y) was investigated for the MP30MGy films (M2 MGs)—see FIG. 15B. These results confirm that the PL intensity increase was associated with formation of an extensive DIO film for MP30MG3.0 (see FIG. 8H). A high PL intensity indicates decreased quenching occurred. As the thickness of the capping layer increases more of the MAPbl_{3-z}Cl_{z} is located further from the mp-TiO₂ and is less able to be quenched. Accordingly, the increased PL intensity for the films (as shown in FIGS. 15A and B) is interpreted as being the result of increased capping layer thickness caused by the micropatterning by the MG particles. In support of this suggestion the capping layers were measured for the MP25 and MP37.5 films and were 175 and 240 nm, respectively. Whereas, the thicknesses of the capping layers for MP25.0MG3.0 and MP37.5MG3.0 films were 195 and 700 nm, respectively.

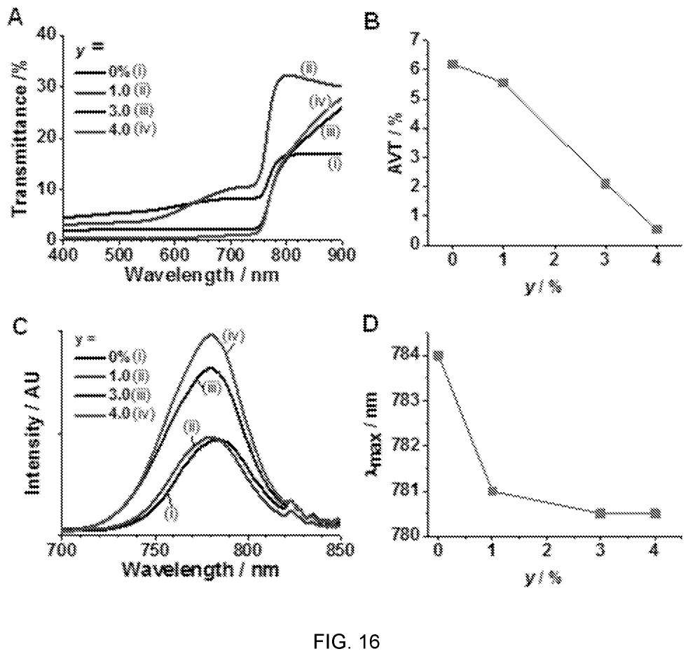

FIG. 16A shows transmittance spectra for the MP30MGy films (prepared according to Method 5 using M3 MGs) wherein y=0, 1, 3 and 4. All these films were strongly absorbing with low transmittance over most of the visible range. Increasing y caused the average visible transmittance (AVT) to decrease (FIG. 16B), which is due to increased light scattering from the two phase films with increasing y. To probe the effects of MG concentration on charge transfer, PL spectra were measured (FIG. 16C). The PL intensity increased with y, which indicates that non-radiative recombination became increasingly less efficient. Furthermore, a significant blue shift of the wavelength at maximum PL intensity (λₘₐₓ) occurred with increasing y (see FIG. 16D).

### Method 6—Solar Cell Fabrication

The procedure to prepare the ITO/bl-TiO₂/mp-TiO₂/MAPbl_{3-z}Cl_{z} (MPx) and ITO/bl-TiO₂/mp-TiO₂/MAPbl_{3-z}Cl_{z}/MGs (MPxMGy) films was as described above in Method 5, prepared using MGs according to Method 2. A hole transport layer (spiro film −200 nm) was formed by spin-coating LiTFSI (4.8 μL, 520 mg/ml) and TBP (8.0 μL) in CBZ as solvent at room temperature at 4000 rpm for 20 s onto the MPx and MPxMGy films. Then all devices were coated with a gold layer (70 nm) by thermal evaporation.

PSC devices with MP25MG3.0, MP37.5MG3.0 and MP45MG2.0 DIO layers were constructed. Control devices were also constructed using MP25, MP37.5 and MP45 photoactive layers.

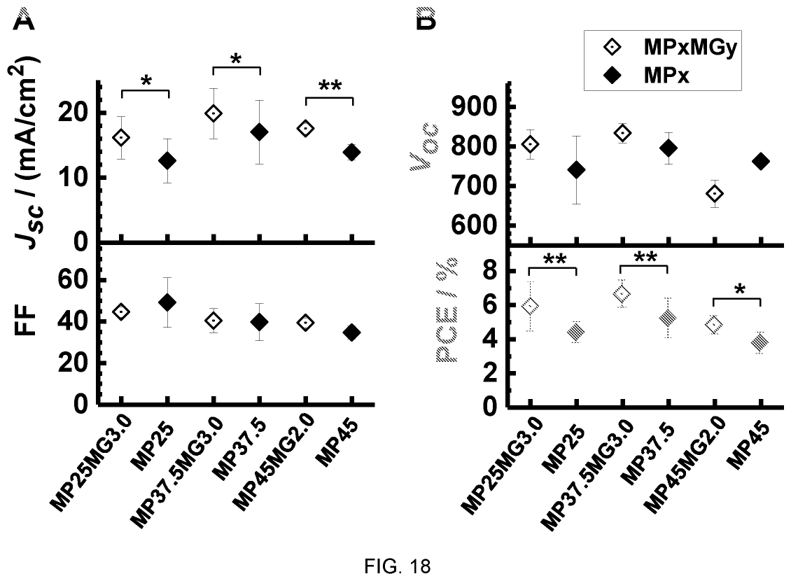

Representative J-V curves are shown in FIG. 17B which demonstrate that operational PSCs were prepared in all cases. The figures of merit extracted from the J-V data are shown in Table B and FIG. 18.

TABLE B

| Devices | J_{sc} (mA/cm⁻²) | V_{oc} (mV) | FF (%) | PCE (%) |
|---|---|---|---|---|
| MP25.0 | 12.62 ± 3.40 | 740 ± 86 | 49.2 ± 12.0 | 4.33 ± 0.62 |
| MP25MG3.0 | 16.15 ± 3.27 | 806 ± 37 | 44.6 ± 2.5 | 5.85 ± 1.45 |
| MP37.5 | 17.04 ± 4.91 | 795 ± 40 | 39.7 ± 8.9 | 5.15 ± 1.16 |
| MP37.5MG3.0 | 19.88 ± 3.89 | 834 ± 25 | 40.5 ± 5.8 | 6.58 ± 0.81 |
| MP45.0 | 13.92 ± 1.20 | 762 ± 10 | 34.7 ± 3.1 | 3.70 ± 0.63 |
| MP45MG2.0 | 17.53 ± 0.81 | 680 ± 34 | 39.4 ± 2.3 | 4.76 ± 0.53 |

The DIO films had significantly higher J_{sc} values compared to the respective control samples in all cases. This result implies that the MG particles increased photo-induced charge transport in the vertical direction and is attributed to more capping layer being retained. The UV-visible spectra clearly showed that the MGs increased the light absorption from MAPbl_{3-z}Cl_{z}, especially in the blue region (see FIG. 14B). This increased light harvesting would have contributed to J_{sc}. Notably, the PCE values for the DIO films were all significantly higher than those for the respective controls. The PCE values for the devices containing MGs were on average 31% higher than the control devices prepared without MGs. Consequently, the MG particles enhanced the performance of these MAPbl_{3-z}Cl_{z} PSCs. This result may be attributed to the observed increased J_{sc} values.

1. A porous photoactive layer for a perovskite solar cell comprising:
a hybrid inorganic-organic perovskite of formula ABX₃, wherein:
A is C₁₋₆alkyl-NH₃⁺ and optionally also includes one or more of Cs⁺, Rb⁺, Ba²⁺, and formamidinium;
B is selected from Pb²⁺ and Sn²⁺; and
X is selected from one or more of Br⁻, Cl⁻ and I⁻;
provided that A and B balance the X⁻ charge, so that overall A is singly-charged and B is doubly-charged; and
a plurality of microgel particles formed from a hydrophilic crosslinked polymeric material capable of swelling in polar aprotic solvents.

2. The porous photoactive layer according to claim 1, wherein the microgel particles comprise a co-polymer of monomers (I) and (II): 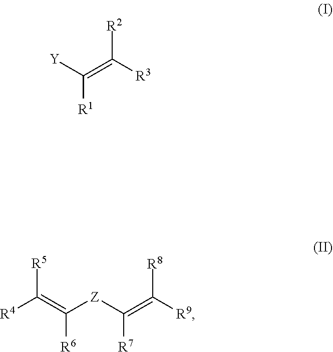
wherein:
Y is selected from: 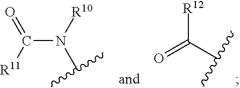
Z is selected from one of the following linkers: 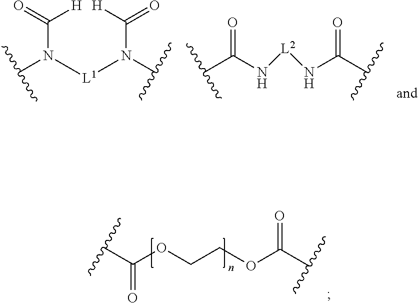
R¹, R², R³, R⁴, R⁵, R⁶, R⁷, R⁸ and R⁹ are independently selected from hydrogen and C₁₋₃alkyl;
R¹⁰ and R¹¹ are independently selected from hydrogen and C₁₋₃alkyl; or
R¹³ and R¹⁴ are taken together with the moieties to which they are attached to form a 4- to 9-membered lactam;
R¹² is selected from NR¹³R¹⁴ and —(OCH₂CH₂)ₚ—OH;
R¹³ and R¹⁴ are independently selected from hydrogen and C₁-3alkyl;
L¹ and L² are independently selected from divalent alkyl, divalent alkylether, divalent alkylamine, divalent alkylamide and divalent alkylester linker groups;
n is 1 to 20; and
p is 2 to 20.

3. The porous photoactive layer according to claim 2, wherein Z is selected from:

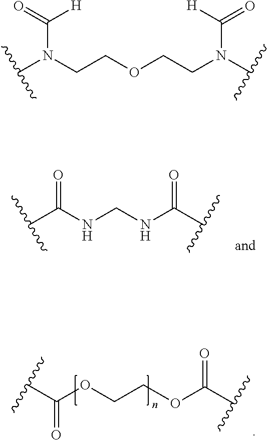

4. The porous photoactive layer according to claim 1, wherein A is C₁₋₆alkyl-NH₃⁺.

5. The porous photoactive layer according to claim 1, wherein B is Pb²⁺.

6. The porous photoactive layer according to claim 1, wherein A is CH₃NH₃⁺, B is Pb²⁺ and X is a combination of Cl⁻ and I⁻.

7. The porous photoactive layer according to claim 2, wherein Y is: 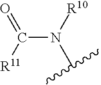
and R¹⁰ and R¹¹ are both hydrogen.

8. The porous photoactive layer according to claim 2, wherein Y is: 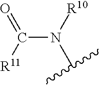
and R¹⁰ and R¹¹ are taken together with the moieties to which they are attached to form a 4- to 9-membered lactam.

9. (canceled)

10. The porous photoactive layer according to claim 2, wherein Y is: 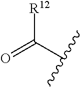
and R¹² is NR¹³R¹⁴.

11. The porous photoactive layer according to claim 10, wherein R¹³ and R¹⁴ are both hydrogen.

12. The porous photoactive layer according to claim 10, wherein R¹³ is hydrogen and R¹⁴ is isopropyl.

13. The porous photoactive layer according to claim 1, having an average pore size in the range 100-5000 nm.

14. (canceled)

15. The porous photoactive layer according to claim 1, wherein the pores in the porous photoactive layer coincide with the location of the microgel particles.

16. The porous photoactive layer according to claim 1, wherein the porous photoactive layer has a disordered inverse opal morphology.

17. The porous photoactive layer according to claim 16, wherein the disordered inverse opal morphology covers greater than 60% of the photoactive layer surface.

18. A method of forming the porous photoactive layer according to claim 1, comprising the steps of:
a) swelling particles of the microgel in a solvent to 1.2-100 times the size of the unswollen particles;
b) adding hybrid inorganic-organic perovskite precursors to the dispersion of swollen microgel particles from step a);
c) coating the dispersion from step b) onto a substrate; and
d) evaporating the solvent.

19. The method according to claim 18, wherein the solvent is selected from γ-butyrolactone, dimethyl formamide, dimethyl sulfoxide, or a combination of these solvents.

20. The method according to claim 18, wherein the hybrid inorganic-organic perovskite precursors are of the formula AX and BX₂, wherein A, B and X are as defined in claim 1.

21. (canceled)

22. The method according to claim 18, wherein step c) further comprises the addition of an anti-solvent during coating.

23. The method according to step 22, wherein the anti-solvent is selected from chlorobenzene, benzene, xylene, toluene, methanol, ethanol, ethylene glycol, 2-propanol, chloroform, THF, acetonitrile, and benzonitrile.

24. (canceled)

25. (canceled)
